(19) United States
(12) Patent Application Publication
(10) Pub. No.: US 2017/0075571 A1
(43) Pub. Date: Mar. 16, 2017

(54) MEMORY DEVICE AND CONTROL METHOD THEREOF

(71) Applicant: Media Tek Inc., Hsin-Chu (TW)

(72) Inventors: Chun-Hung CHEN, Taichung City (TW); Yi-Hung CHEN, Hsinchu City (TW)

(21) Appl. No.: 14/851,208

(22) Filed: Sep. 11, 2015

(51) Int. Cl. G06F 3/06; G06F 12/08; G11C 11/418

(52) U.S. Cl. CPC G06F 3/061; G11C 11/418; G06F 3/0638; G06F 3/0683; G06F 12/0895; G06F 2212/1016; G06F 2212/221

(57) ABSTRACT

A memory device is provided. The memory device includes a plurality of memory banks, at least one buffer bank and a controller. Each memory bank has a bank index and includes a plurality of bank memory units for storing data associated with a logical address corresponding to the bank index. The buffer bank includes a plurality of buffer memory units. The controller receives a read command and a write command in a first clock cycle, wherein the read command and the write command are requesting to access a specific memory bank among the memory banks. If an access request of the read command and the write command exceeds a bandwidth limitation of the specific memory bank, the controller utilizes the buffer bank to accomplish the read command and the write command.

### BACKGROUND OF THE INVENTION

Field of the Invention

The invention relates to a multi-port memory device, and more particularly to a control method for increasing bandwidth of a multi-port memory device.

Description of the Related Art

Current trends in the semiconductor and electronics industry require memory devices to be made smaller, faster and require less power consumption. One reason for these trends is that more relatively small and portable personal devices are being manufactured, thereby relying on battery power. In addition to being smaller and more portable, personal devices are also requiring increased memory and more computational power and speed. In light of all these trends, there is an ever increasing demand in the industry for smaller size, faster speed, higher capacity, and lower power dissipation memory cells and transistors used to provide the core functionality of the memory devices.

The speed at the processors of various electronic devices has been continually increasing. Specifically, decreasing the size of the semiconductor transistors and decreasing the operating voltages of these transistors has allowed processor clocks to run at faster rates. Thus, Static Random Access Memory (SRAM) based cache memory systems are often used. SRAM devices operate at much faster rates than DRAM devices but have a lower memory density, consume more power, and are more expensive.

### BRIEF SUMMARY OF THE INVENTION

A memory device and a control method thereof are provided. An embodiment of a memory device is provided. The memory device comprises a plurality of memory banks, at least one buffer bank and a controller. Each of memory banks has a bank index and comprises a plurality of bank memory units for storing data associated with a logical address corresponding to the bank index. Each of the at least one buffer bank comprises a plurality of buffer memory units. The controller receives at least one read command and at least one write command in a first clock cycle, wherein the at least one read command and the at least one write command are requesting to access a specific memory bank among the memory banks. If an access request of the at least one read command and the at least one write command exceeds a bandwidth limitation of the specific memory bank, the controller utilizes the at least one buffer bank to accomplish the at least one read command and the at least one write command.

Furthermore, an embodiment of a control method for accessing a memory device is provided, wherein the memory device comprising a plurality of memory banks and at least one buffer bank. At least one read command and at least one write command are received in a first clock cycle, wherein the at least one read command and the at least one write command are requesting to access a specific memory bank among the memory banks. The at least one buffer bank is utilized to accomplish the at least one read command and the at least one write command when an access request of the at least one read command and the at least one write command exceeds a bandwidth limitation of the specific memory bank. Each of the memory banks has a bank index and comprises a plurality of bank memory units for storing data associated with a logical address corresponding to the bank index. Each of the least one buffer bank comprises a plurality of buffer memory units.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a multi-port memory device according to an embodiment of the invention;

FIG. 2 shows a two-port memory device according to an embodiment of the invention;

FIG. 3 shows a control method for a memory device according to an embodiment of the invention;

FIG. 4 shows an example waveform diagram of the buses of the memory device of FIG. 2 according to the control method of FIG. 3;

FIGS. 5A-5D show a two-port latency-reduced memory device according to another embodiment of the invention;

FIGS. 6A-6C show a control method for a latency-reduced memory device according to an embodiment of the invention;

FIGS. 7A-7B show an example waveform diagram of the buses of the memory device of FIGS. 5A-5D according to the control method of FIGS. 6A-6C;

FIG. 8 shows a two-port latency-reduced memory device according to another embodiment of the invention;

FIGS. 9A-9C show a control method for a latency-reduced memory device according to another embodiment of the invention;

FIG. 10 shows an example waveform diagram of the buses of the memory device of FIG. 8 according to the control method of FIGS. 9A-9C; and

FIG. 11 shows a flow chart illustrating the write-to-buffer-bank process of the control method of FIGS. 9A-9C according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

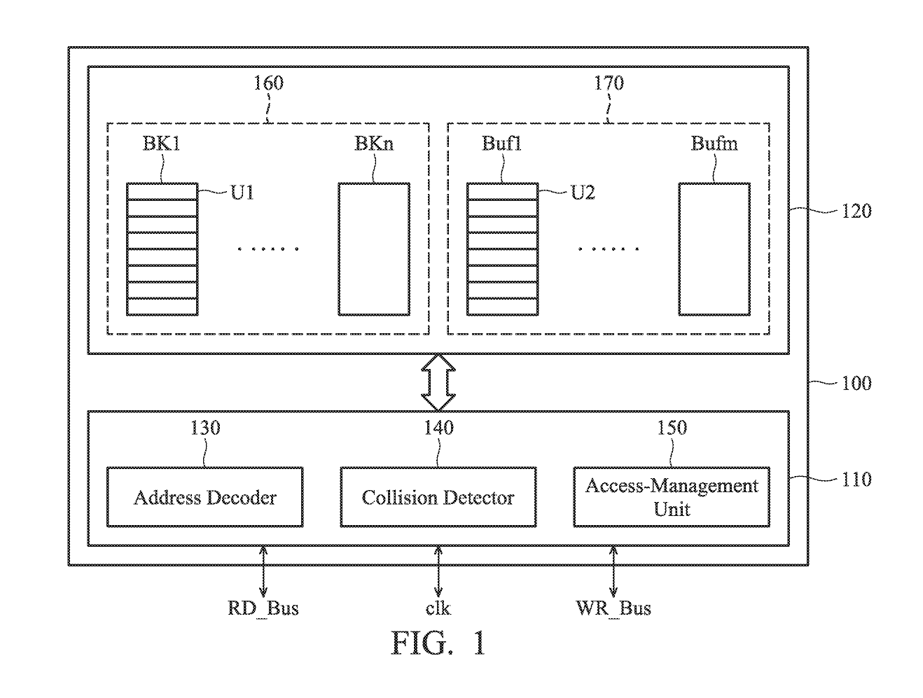

FIG. 1 shows a multi-port memory device 100 according to an embodiment of the invention. The memory device 100 comprises a controller 110 and a memory circuit 120, wherein the memory device 100 can be accessed by other devices (e.g. a host) via a bus RD_Bus for reading and via a bus WR_Bus for writing according to a clock signal clk from the devices. The memory circuit 120 comprises a main part 160 and a buffer part 170, wherein the main part 160 comprises a plurality of memory banks BK1-BKn, and the buffer part 170 comprises one or more buffer banks. Each of the memory banks BK1-BKn has an individual bank index, and comprises a plurality of memory units U1 for storing data associated with a logical address corresponding to the bank index. Furthermore, each of the buffer banks Buf1-Bufm comprises a plurality of memory units U2 for accessing one of the memory banks BK1-BKn when an access request exceeds a bandwidth limitation of the one of the memory banks BK1-BKn. The controller 110 comprises an address decoder 130, a collision detector 140 and an access-management unit 150. The address decoder 130 translates the logical addresses from the buses RD_Bus and WR_Bus into the corresponding physical addresses and the corresponding bank indexes. The collision detector 140 detects whether the read and write commands collide at the same physical memory bank according to the physical addresses of the read and write commands. The access-management unit 150 manages an access sequence for the memory banks BK1-BKn and the buffer banks Buf1-Bufm of the memory circuit 120. It is to be noted that the port number of the memory device 100 is determined according to various applications. Furthermore, each of the memory banks BK1-BKn may be a memory bank having a plurality of R/W ports, or a memory bank having a plurality of read ports combined with a plurality of write ports. Specifically, a plurality of memory banks are used to increase the total memory bandwidth for the memory device 100. The memory device 100 may be a two-port (1R1W) memory device, a dual-port (2RW) memory device, a 2 read port-1 write port (2R1W) memory device, a 1 read port-2 write port (1R2W) memory device, or a 2 read port-2 write port (2R2W) memory device, but is not limited thereto. To be specific, the type of the memory device of the present application is determined according to the type of the memory banks within the memory device and the type of the buffer banks within the memory device.

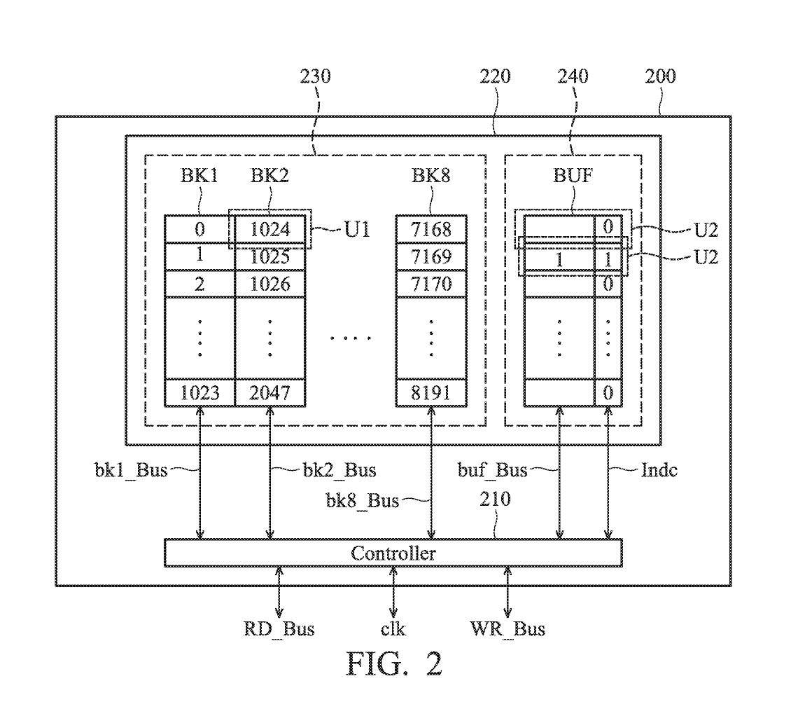

FIG. 2 shows a two-port memory device 200 according to an embodiment of the invention. The two-port memory device 200 comprises a controller 210 and a memory circuit 220, wherein the memory circuit 220 comprises a main part 230 and a buffer part 240. The main part 230 comprises 8 memory banks BK1-BK8, and each of the memory banks BK1-BK8 is a single port memory bank having 1024 memory units U1. In the embodiment, the controller 210 accesses the memory circuit 220 according to the buses RD_Bus and WR_Bus and the clock signal clk. Furthermore, the controller 210 can access each of the memory banks BK1-BK8 via the corresponding buses. For example, the controller 210 can access the memory bank BK1 via the bus bk1_Bus, the memory bank BK2 via the bus bk2_Bus and so on. The buffer part 240 comprises a buffer bank BUF, and the buffer bank BUF is a two-port memory bank having 1024 memory units U2, wherein each memory unit U2 comprises a data area and an indicator area. In the embodiment, the controller 210 can access the data areas of the buffer bank BUF via the bus buf_Bus, and access the indicator areas of the buffer bank BUF via the bus Indc. A quantity of the memory units U2 of the buffer bank BUF is equal to a quantity of the memory units U1 of each of the memory banks BK1-BK8. Furthermore, the memory units U1 of each of the memory banks BK1-BK8 having the same entry index correspond to the same memory unit U2 of the buffer bank BUF. In one embodiment, the buffer bank BUF comprises 2048 memory units U2, i.e. a quantity of the memory units U2 of the buffer bank BUF is larger than a quantity of the memory units U1 of each of the memory banks BK1-BK8. For example, the memory units U2 are divided into two parts, wherein a half of the memory units U2 are used to accomplish the accessing for the odd number memory banks (e.g. BK1, BK3. BK5 and BK7), and another half of the memory units U2 are used to accomplish the accessing for the even number memory banks (e.g. BK2, BK4, BK6 and BK8).

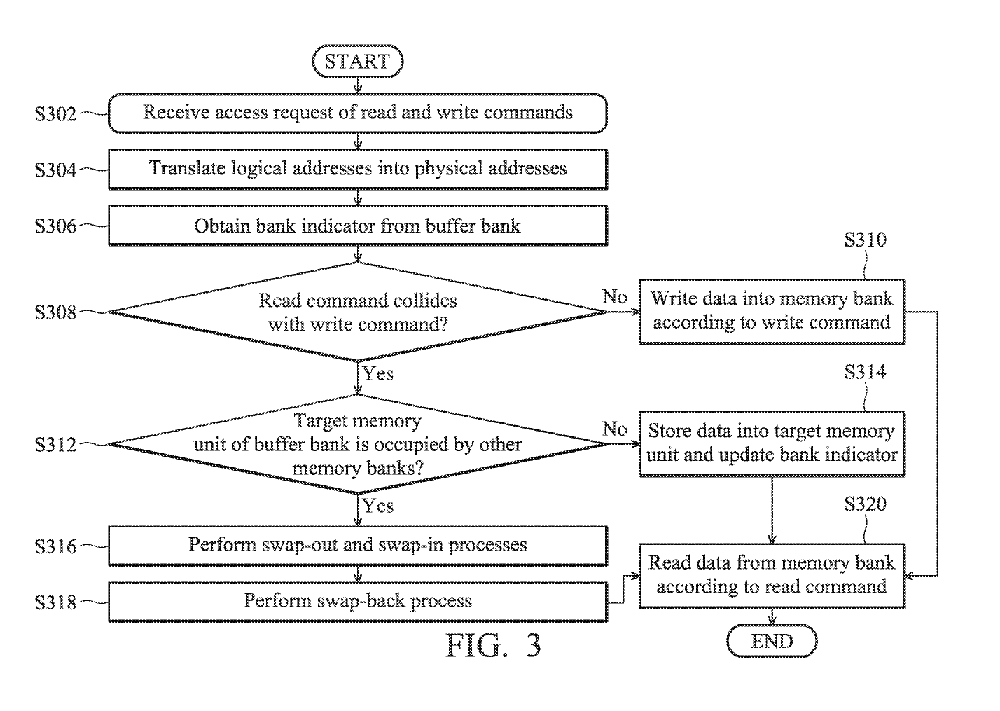

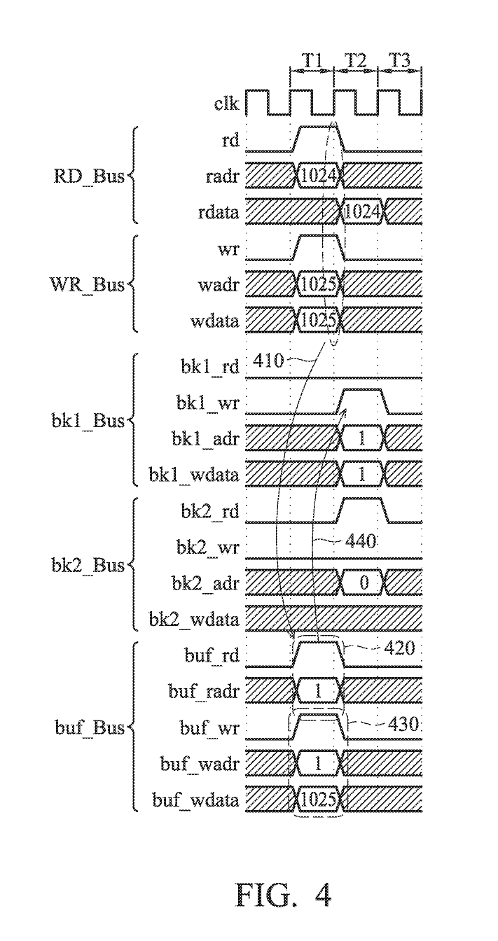

FIG. 3 shows a control method for a memory device according to an embodiment of the invention, and FIG. 4 shows an example waveform diagram of the buses of the memory device 200 of FIG. 2 according to the control method of FIG. 3. In FIG. 4, the bus RD_Bus comprises a command signal rd, an address signal radr and a data signal rdata for a read port of the memory device 200 in FIG. 2. Furthermore, the bus WR_Bus comprises a command signal wr, an address signal wadr and a data signal wdata for a write port of the memory device 200 in FIG. 2. For each of the memory banks BK1-BK8, each bus comprises two command signals bk#_rd and bk#_wr, an address signal bk#_adr and a data signal bk#_wdata. For example, the bus bk1_Bus of the memory bank BK1 comprises the command signal bk1_rd, the command signal bk1_wr, the address signal bk1_adr and the data signal bk1_wdata, and the bus bk2_Bus of the memory bank BK2 comprises the command signal bk2_rd, the command signal bk2_wr, the address signal bk2_adr and the data signal bk2_wdata. Moreover, the bus buf_Bus of the buffer bank BUF comprises a command signal buf_rd and an address signal buf_radr for a read port, and a command signal buf_wr, an address signal buf_wadr and a data signal buf_wdata for a write port.

Referring to FIGS. 2-4 together, first, in step S302, the memory device 200 receives an access request of a read command and a write command, e.g. the command signal rd of the bus RD_bus and the command signal wr of the WR_bus are present at a clock cycle T1 of FIG. 4. Next, in step S304, an address decoder (e.g. 130 of FIG. 1) of the controller 210 translates a logical address obtained in the address signal radr of the bus RD_bus into a read physical address and a read bank index, and translates a logical address obtained in the address signal wadr of the bus WR_bus into a write physical address and a write bank index. For example, in the clock cycle T1, the address decoder will translate the logical address “1024” of the address signal radr into the read physical address “0” and a read bank index “2”, and translate the logical address “1025” of the address signal wadr into the write physical address “1′” and a write bank index “2”. Next, in step S306, according to the read and write physical addresses, an access-management unit (e.g. 150 of FIG. 1) of the controller 210 reads the indicator areas of the memory units U2 in the buffer bank BUF via the bus Indc, to obtain the bank indicators corresponding to the read and write physical addresses, respectively. For example, in FIG. 4, the bank indicator corresponding to the read physical address “0” is “0”, and the bank indicator corresponding to the write physical address “1” is “1”. Next, in step S308, a collision detector (e.g. 140 of FIG. 1) of the controller 210 determines whether the read command collides with the write command, i.e. the memory banks corresponding to the write and read bank indexes are the same memory bank. Specifically, the access request of the read command and the write command exceeds a bandwidth limitation of the memory bank, i.e. the memory bank does not have enough write ports or read/write ports to access the memory bank when the memory bank is read. If the read command does not collide with the write command, the access-management unit writes the data from the data signal wdata of the bus WR_Bus into the memory unit of the memory bank according to the write bank index and the write physical address at a clock cycle T2 immediately following the clock cycle T1 (step S310). Next, in step S320, the access-management unit reads the memory unit U1 of the memory bank corresponding to the read bank index and the read physical address at the clock cycle T2. Thus, the access request is completed. However, in the present embodiment, the read command collides with the write command, i.e. the write and read bank indexes are the same (as shown in label 410 of FIG. 4), it is further determined whether a target memory unit of the buffer bank BUF is occupied by other memory banks (step S312), wherein the target memory unit is the memory unit U2 corresponding to the write physical address in the buffer bank BUF (i.e., the second entry of the buffer bank BUF). To be specific, it is determined whether the bank indicator corresponding to the write physical address obtained in step S306 is equal to or different from the write bank index obtained in step S304. If the target memory unit of the buffer bank BUF is not occupied, e.g. the bank indicator is equal to “0”, the access-management unit stores the data obtained in the data signal wdata of the bus WR_Bus into the target memory unit U2 of the buffer bank BUF, and updates the bank indicator of the target memory unit according to the write bank index (step S314), i.e. the bank indicator is set to the write bank index. Next, the access-management unit reads the memory unit U1 of the memory bank corresponding to the read bank index and the read physical address (step S320), thereby the access request is completed. However, in the present embodiment, the target memory unit of the buffer bank BUF is occupied (the bank indicator is not equal to “0”), a swap-out process and a swap-in process are performed for the target memory unit at the clock cycle T1 (step S316). In the swap-out process, the access-management unit reads the target memory unit to obtain the data and the bank indicator stored in the target memory unit, as the swap-out data and the swap-out indicator, as shown in label 420 of FIG. 4. In the swap-in process, the access-management unit stores the data obtained in the data signal wdata of the bus WR_Bus into the target memory unit, and updates the bank indicator of the target memory unit in the buffer bank BUF according to the write bank index, as shown in label 430 of FIG. 4. Next, a swap-back process is performed at the clock cycle T2 (step S318), so as to store a swap-back data (i.e. the swap-out data) into the corresponding memory unit of the memory bank according to the swap-out indicator and the entry index of the buffer memory unit used for storing the swap-back data (i.e. the swap-out data) previously, wherein the access-management unit obtains a swap-back address according to the swap-out indicator and the entry index. In this embodiment, the swap-back data will be stored into the second bank memory unit of the memory bank BK1 according to the swap-back address, as shown in label 440 of FIG. 4. Next, the access-management unit reads the memory unit U1 of the memory bank corresponding to the read bank index and the read physical address at the clock cycle T2 (step S320), thereby the access request is completed. Furthermore, in FIG. 3, steps S308-S318 are performed for the actions of the write command, and step S320 is performed for the actions of the read command. Moreover, steps S312, S314, S316 and S318 are also referred to as the write-to-buffer-bank process. As shown in FIG. 4, the actions corresponding to the read command is performed at the clock cycle T2. i.e. the read action is delayed for one clock cycle. Furthermore, in one embodiment, if the read command collides with the write command and the bank indicator of target memory unit of the buffer bank BUF is occupied by the memory bank corresponding to the write command, the access-management unit may direct update the data area of the target memory unit of the buffer bank BUF in response to the write command, thus no collision exists and the bank indicator of the target memory unit will not be modified. Alternatively, if the read command collides with the write command and the bank indicator of target memory unit of the buffer bank BUF is occupied by the memory bank corresponding to the write command, steps S308-S318 are performed for the actions of the write command and step S320 is performed for the actions of the read command, thereby the access request is completed.

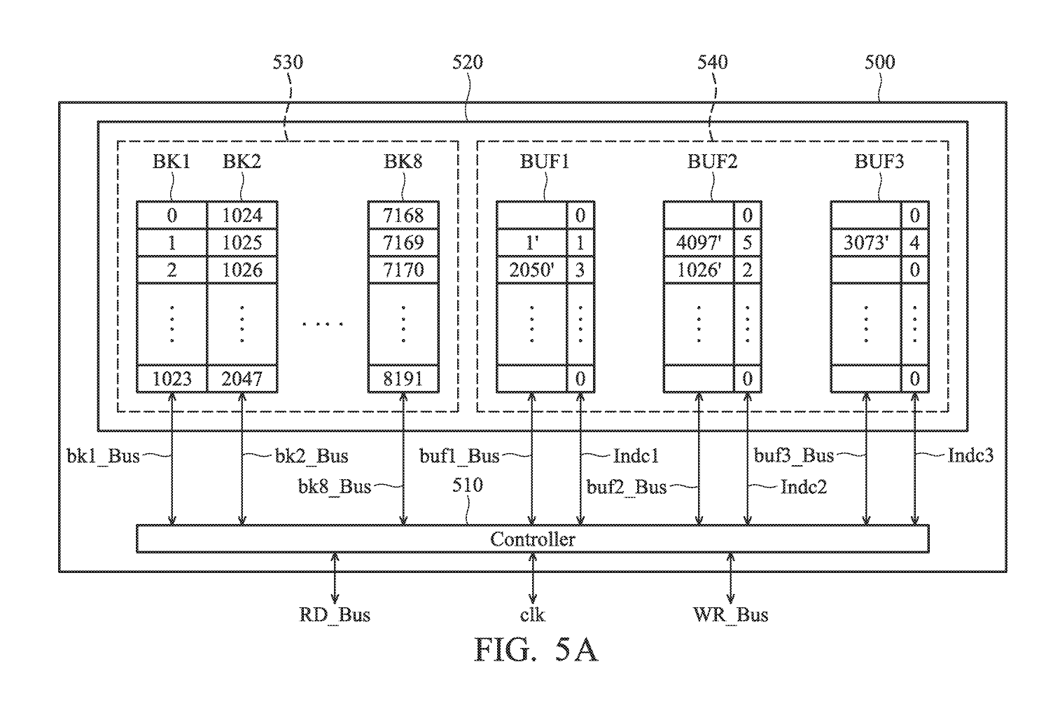

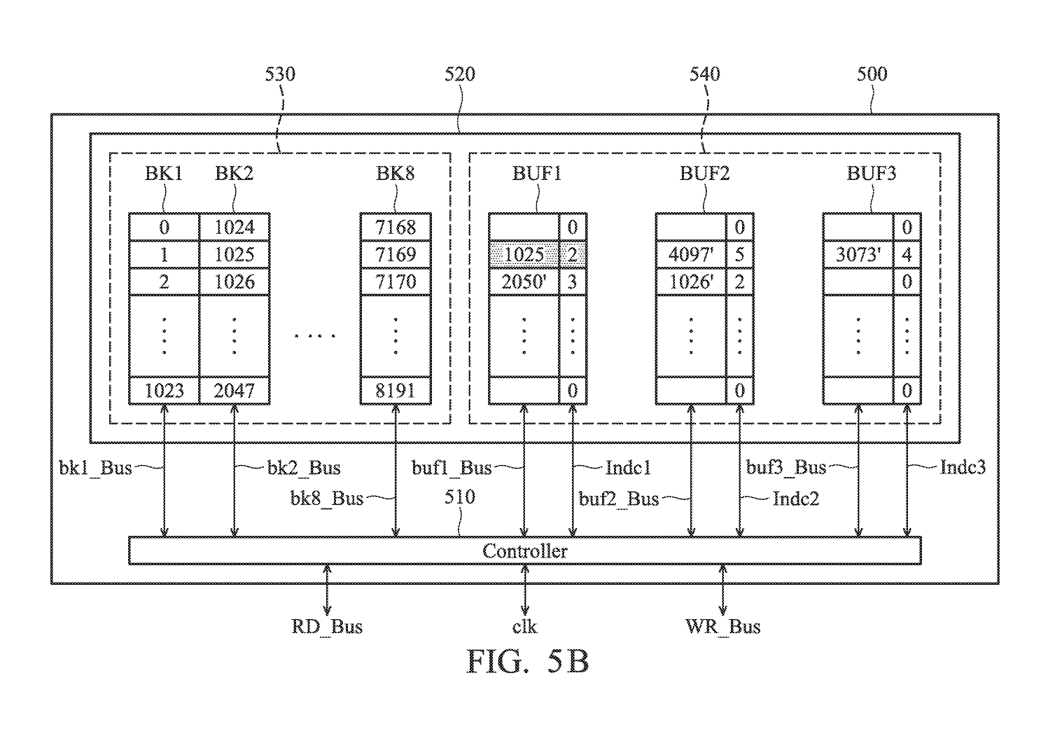

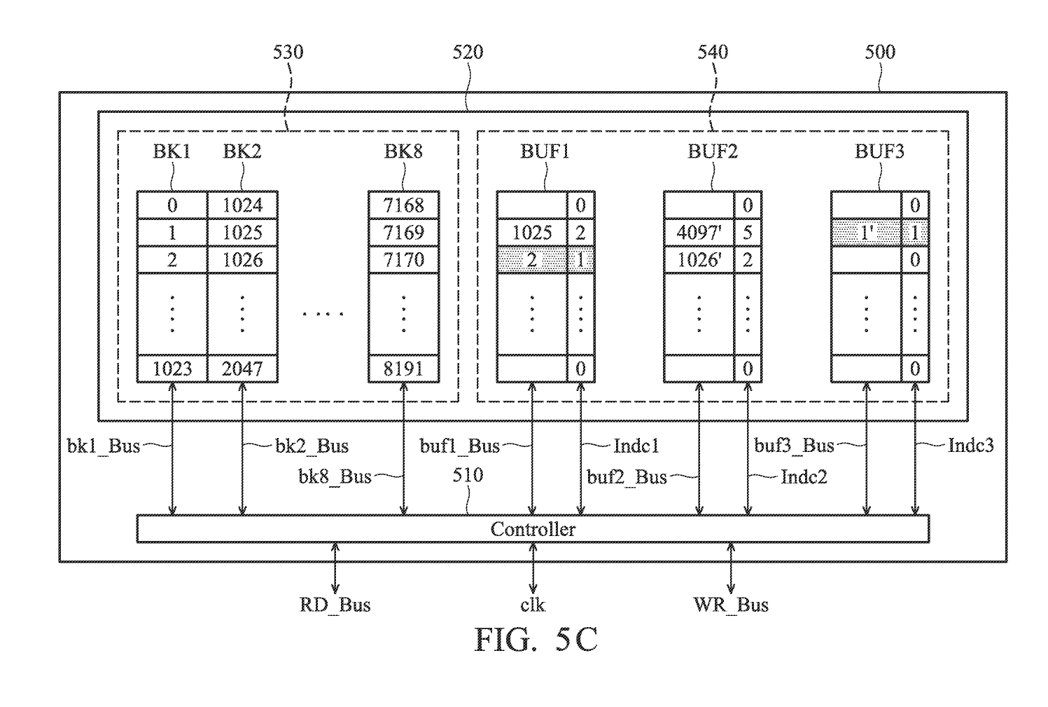

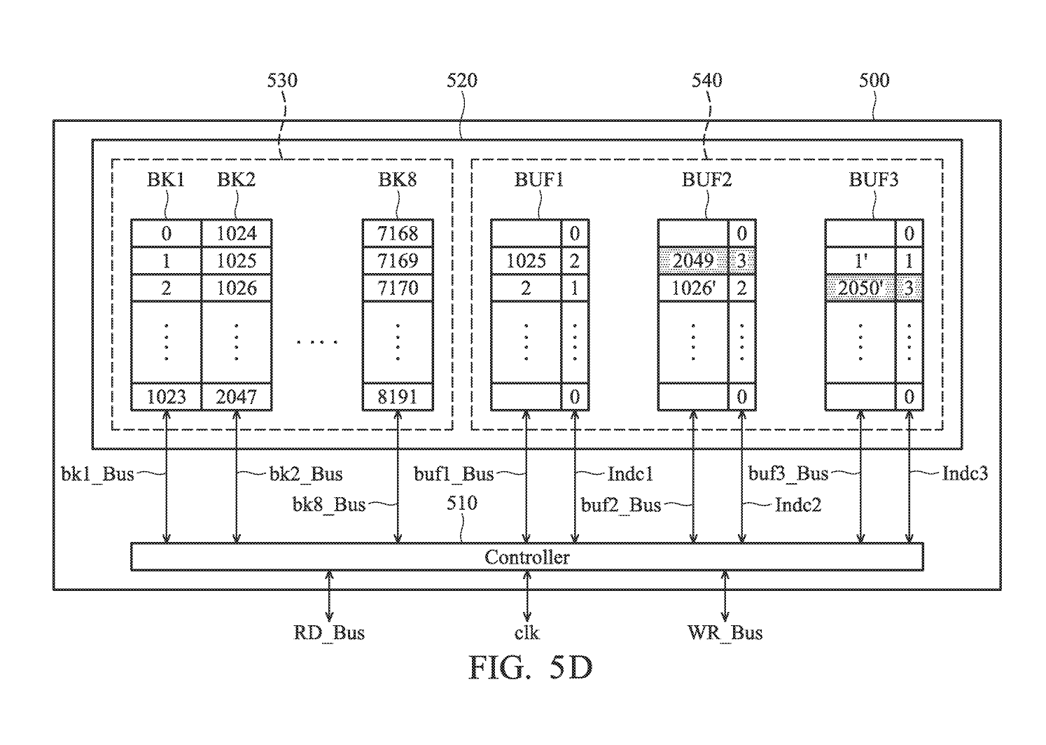

FIGS. 5A-5D shows a two-port latency-reduced memory device 500 according to another embodiment of the invention. The two-port memory device 500 comprises a controller 510 and a memory circuit 520, wherein the memory circuit 520 comprises a main part 530 and a buffer part 540. The main part 530 comprises 8 memory banks BK1-BK8, and each of the memory banks BK1-BK8 is a single port memory bank having 1024 memory units U1. The buffer part 540 comprises three buffer banks BUF1-BUF3, and each of the buffer banks BUF1-BUF3 is a two-port memory bank having 1024 memory units U2. As described above, each memory unit U2 comprises a data area and an indicator area.

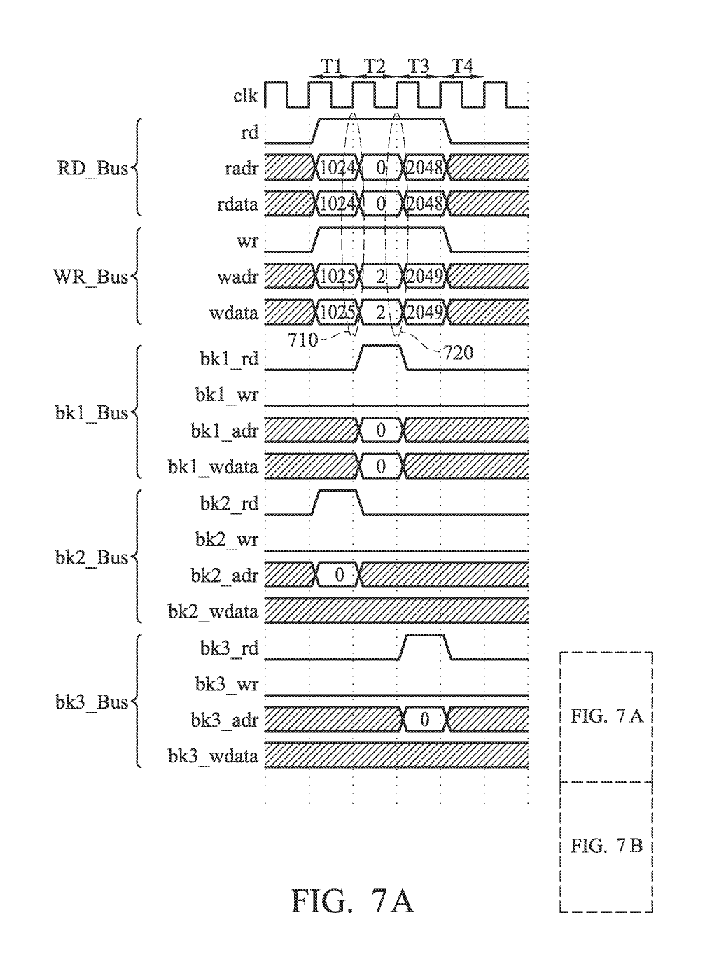

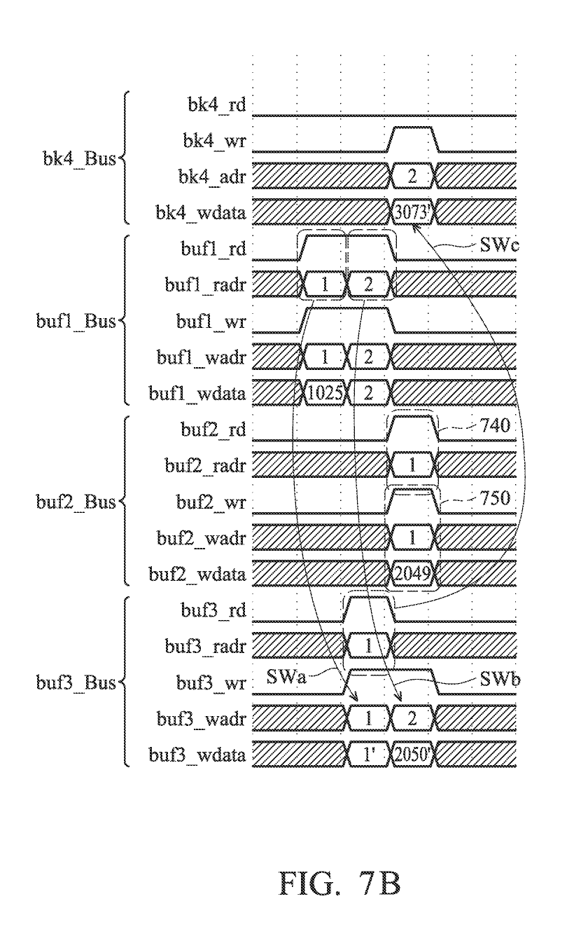

FIGS. 7A-7B show an example waveform diagram of the buses of the memory device 500 of FIGS. 5A-5D. In FIGS. 7A-7B, the bus RD_Bus comprises a command signal rd, an address signal radr and a data signal rdata for a read port of the memory device 500 in FIGS. 5A-5D. Furthermore, the bus WR_Bus comprises a command signal wr, an address signal wadr and a data signal wdata for a write port of the memory device 500 in FIGS. 5A-5D. Furthermore, for each of the memory banks BK1-BK8, each bus comprises two command signals bk#_rd and bk#_wr, an address signal bk#_adr and a data signal bk#_wdata, as described above. Moreover, for each of the buffer banks BUF1-BUF3, each bus comprises a command signal buf#_rd and an address signal buf#_radr for a read port, and a command signal buf#_wr, an address signal buf#_wadr and a data signal buf#_wdata for a write port. For example, the bus buf1_Bus of the buffer bank BUF1 comprises the command signal buf1_rd, the address signal buf1_radr, the command signal buf1_wr, the address signal buf1_wadr and the data signal buf1_wdata, and the bus buf3_Bus of the buffer bank BUF3 comprises the command signal buf3_rd, the address signal buf3_radr, the command signal buf3_wr, the address signal buf3_wadr and the data signal buf3_wdata.

Referring FIGS. 5A-5D and 7A-7B together. In this embodiment, the initial content of the memory device 500 is shown in FIG. 5A. During clock cycle T1, the memory device 500 receives a first read command and a first write command as shown in FIGS. 7A-7B, wherein the first read command collides with the first write command (as shown in label 710 of FIGS. 7A-7B). The data corresponding to the first read command is read from the memory bank BK2. To handle the collision 710, the data to be written (i.e., “1025”) and the corresponding bank index (i.e., “2”) are written into the second entry of the buffer bank BUF1 as shown in FIG. 5B. Since there is already another data stored in the second entry of the buffer bank BUF1 (i.e., the data “1′” and the corresponding bank index “1”), writing data into the second entry of the buffer bank BUF1 (also referred to as a swap-in process) accompanies a swap-out process for the originally stored data, and this situation will introduce a swap-back command in the next clock cycle (i.e., clock cycle T2). The swap-back command is labeled as SWa in FIG. 7B. The content of the memory device 500 at the end of clock cycle T1 is shown in FIG. 5B.

During clock cycle T2, the memory device 500 receives a second read command, a second write command and a swap-back command caused by the previous clock cycle T1, wherein the second read command collides with the second write command (as shown in label 720 of FIGS. 7A-7B). The data corresponding to the second read command is read from the memory bank BK1. As shown in FIG. 5C, the data corresponding to the second write command is written into the third entry of the buffer bank BUF1. Since there is already a data stored therein, it causes a swap-out process for the originally stored data (i.e., data “2050”’ and the bank index “3”) and a swap-in process for the data corresponding to the second write command (i.e., data “2” and the bank index “1”) in the clock cycle T2, and introduces a swap-back command (labeled as SWb in FIG. 7B) in the clock cycle T3. The data corresponding to the swap-back command SWa is written into the second entry of the buffer bank BUF3, this operation causes a swap-out process for the originally stored data (i.e., data “3073” and the bank index “4”) and a swap-in process for the data corresponding to the swap-back command SWa (i.e., data “1′” and the bank index “1”) in the clock cycle T2, and also introduces a swap-back command (labeled as SWc in FIG. 7B) in the clock cycle T3. The content of the memory device 500 at the end of clock cycle T2 is shown in FIG. 5C.

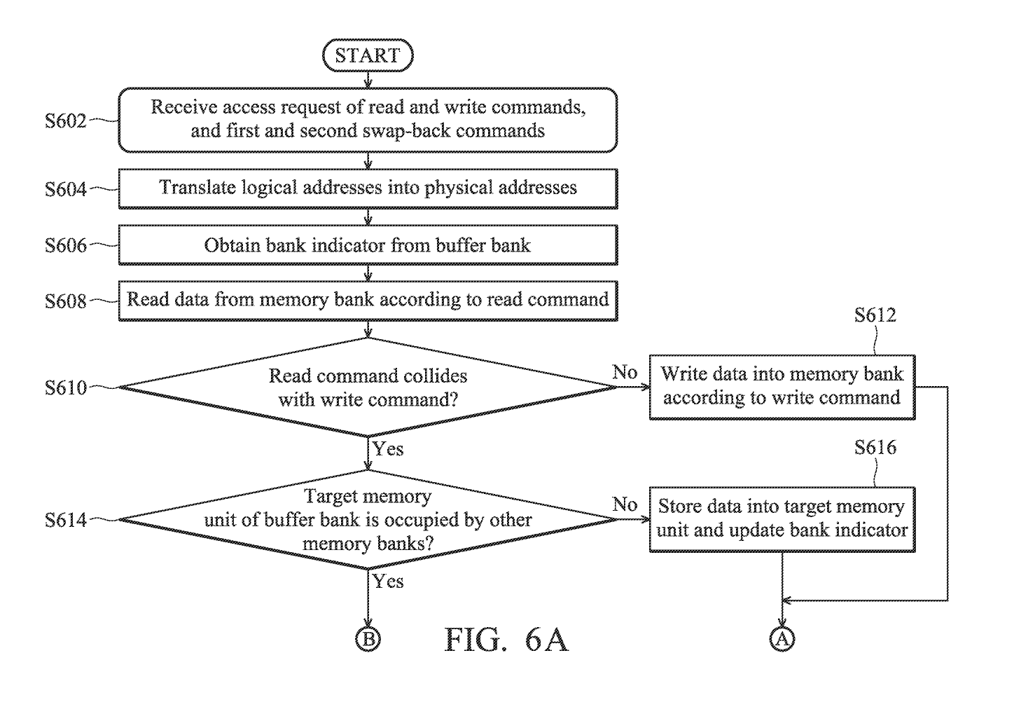

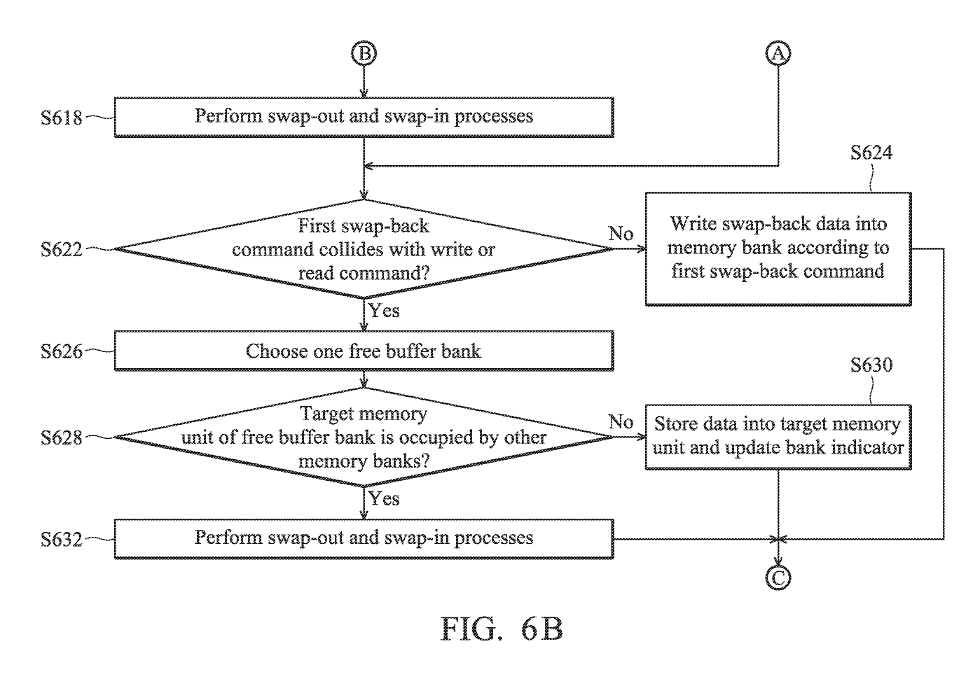

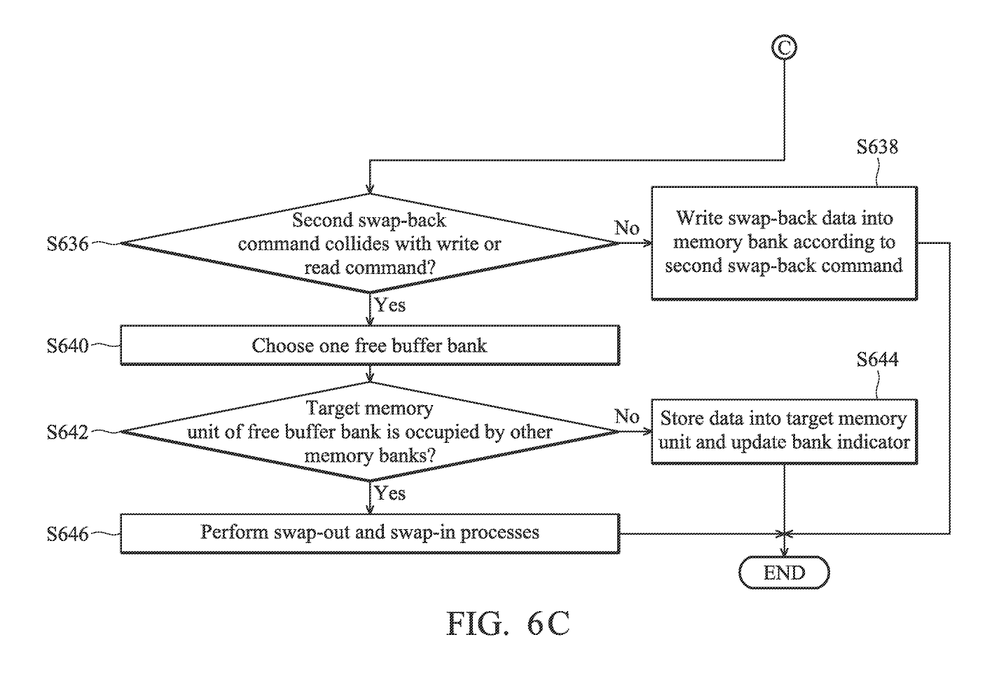

Please refer to FIG. 6A-6C as a flow diagram for the detailed operations of memory device 500 during clock cycle T3. In step S602, the memory device 500 receives an access request of a read command and a write command (e.g. the command signal rd of the bus RD_bus and the command signal wr of the WR_bus are present at a clock cycle T3 of FIGS. 7A-7B), a first swap-back command SWb and a second swap-back command SWc, wherein a swap-back process needing to be performed in response to any swap-back command. Next, in step S604, an address decoder (e.g. 130 of FIG. 1) of the controller 510 translates a logical address obtained in the address signal radr of the bus RD_bus into a read physical address and a read bank index, and translates a logical address obtained in the address signal wadr of the bus WR_bus into a write physical address and a write bank index in the clock cycle T3. For example, the address decoder will translate the logical address “2048” of the address signal radr into the read physical address “0” and a read bank index “3”, and translate the logical address “2049” of the address signal wadr into the write physical address “1” and a read bank index “3”. Next, in step S606, according to the read and write physical addresses and the swap-back addresses of the first and second swap-back commands, an access-management unit (e.g. 150 of FIG. 1) of the controller 510 reads the indicator areas of the memory units U2 of the corresponding buffer bank via the corresponding bus, to obtain the bank indicators corresponding to the read and write physical addresses and the bank indicator corresponding to the first and second swap-back command, respectively. Next, in step S608, the access-management unit reads the memory unit U1 of the memory bank corresponding to the read bank index and the read physical address. In the present embodiment, the access-management unit reads out the data stored in the first entry of the memory bank BK3. Next, in step S610, a collision detector (e.g. 140 of FIG. 1) of the controller 510 determines whether the read command collides with the write command, i.e. the memory banks corresponding to the write and read bank indexes are the same memory bank. Specifically, the access request of the read command and the write command exceeds a bandwidth limitation of the memory bank, i.e. the memory bank does not have enough write ports or read/write ports to access the memory bank when the memory bank is read. If the read command does not collide with the write command, e.g. the write and read bank indexes are different, the access-management unit writes the data from the data signal wdata of the bus WR_Bus into the memory unit U1 of the memory bank corresponding to the write bank index and the write physical address (step S612), and then step S622 is performed. Step S622 is illustrated below. In the present embodiment, the read command collides with the write command, that is, the write and read bank indexes are the same as shown in the clock cycle T3, it is further determined whether a target memory unit of a buffer bank is occupied by other memory banks at the clock cycle T3 (step S614). If the target memory unit of the buffer bank is not occupied. e.g. the bank indicator is equal to “0”, the access-management unit stores the data obtained in the data signal wdata of the bus WR_Bus into the target memory unit of the buffer bank, and updates the bank indicator of the target memory unit in the buffer bank according to the write bank index (step S616), i.e. the bank indicator is set to the write bank index, and then step S622 is performed. However, in the present embodiment, the target memory unit of the buffer bank is the second entry of the buffer bank BUF2, and it is occupied by a previously stored data, e.g. the bank indicator is not equal to “0”, a swap-out process and a swap-in process are performed for the target memory unit at the current clock cycle (step S618), and the access-management unit will issue another swap-back command at the next clock cycle (i.e., clock cycle T4). In the swap-out process, the access-management unit reads the target memory unit to obtain the data (i.e., “4097”’) and the bank indicator (i.e., “5”) originally stored in the target memory unit, as the swap-out data and the swap-out indicator, as shown in label 740 of FIG. 7B. In the swap-in process, the access-management unit stores the data obtained in the data signal wdata of the bus WR_Bus into the target memory unit, and updates the bank indicator of the target memory unit in the buffer bank BUF according to the write bank index, as shown in label 750 of FIG. 7B. Furthermore, in FIGS. 6A-6B, steps S610-S618 are performed for the actions of the write command, and step S608 is performed for the actions of the read command. Moreover, as shown in FIGS. 7A and 7B, the actions corresponding to the second read command are performed at the clock cycle T2 immediately, i.e. the read action has not been delayed. In this embodiment, steps S614, S616 and S618 and the issuing and the performing of the swap-back command at the next clock cycle are also referred to as the write-to-buffer-bank process.

Furthermore, the actions of the first swap-back command SWb are performed in steps S622-S632. In step S622 of FIG. 6B, the collision detector determines whether a target bank of the first swap-back command SWb collides with the write or read command, i.e. the memory banks corresponding to the write or read bank indexes and the target bank corresponding to the first swap-back command SWb are the same memory bank. If the first swap-back command SWb does not collide with the write or read command, the access-management unit writes the swap-back data of the first swap-back command SWb into the memory unit U1 of the memory according to a swap-back address of the first swap-back commands SWb (step S624), and step S636 is performed. However, in the present embodiment (i.e., during the clock cycle T3), the first swap-back command SWb collides with the write and read command, so in step S626, the access-management unit chooses a free buffer bank from the buffer banks BUF1-BUF3 to guarantee that no swap-back collision will occur at the next clock cycle. As shown in FIGS. 5D and 7B, the access-management unit chooses the buffer bank BUF3 for storing the data corresponding to the first swap-back command SWb. Next, it is determined whether a target memory unit of the free buffer bank (i.e., the third entry of the buffer bank BUF3) is occupied by other memory banks at the clock cycle T3 (step S628). In the present embodiment, the target memory unit of the free buffer bank is not occupied, e.g. the bank indicator of the target memory unit is equal to “0”, the access-management unit stores the data (i.e., “2050”’) of the first swap-back command into the target memory unit of the free buffer bank, and updates the bank indicator of the target memory unit in the free buffer bank according to a swap-back bank index (i.e., “3”) of the first swap-back command (step S630), and then step S636 is performed. However, in another embodiment, if the target memory unit of the free buffer bank is occupied, e.g. the bank indicator is not equal to “0”, a swap-out process and a swap-in process are performed for the target memory unit at the clock cycle T3 (step S632), and the access-management unit will issue another swap-back command at the next clock cycle (i.e., clock cycle T4). In this embodiment, steps S628, S630 and S632 and the issuing and the performing of the swap-back command at the next clock cycle are also referred to as the write-to-buffer-bank process.

Moreover, the actions of the second swap-back command are performed in FIG. 6C. In step S636 of FIG. 6C, the collision detector determines whether a target bank of the second swap-back command collides with the write or read command, i.e. the memory banks corresponding to the write or read bank indexes and the target bank corresponding to the second swap-back command are the same memory bank. In the present embodiment, the second swap-back command does not collide with the write or read command, the access-management unit writes the swap-back data of the second swap-back command (i.e., “3073′”) into the memory unit U1 of the memory bank (i.e., the third entry of the memory banks BK4) according to a swap-back address of the second swap-back command at the current clock cycle (step S638), and the method is completed. Conversely, if the second swap-back command collides with the write or read command (step S636), in step S640, the access-management unit chooses a free buffer bank from the buffer banks BUF1-BUF3 to guarantee that no swap-back collision will occur at the next clock cycle. Next, it is determined whether a target memory unit of the free buffer bank is occupied by other memory banks at the clock cycle T3 (step S642), wherein the target memory unit is the memory unit corresponding to the swap-back address of the second swap-back command in the free buffer bank. If the target memory unit of the free buffer bank is not occupied, e.g. the bank indicator of the target memory unit is equal to “0”, the access-management unit stores the swap-back data of the second swap-back command into the target memory unit of the free buffer bank, and updates the bank indicator of the target memory unit in the free buffer bank according to a swap-back bank index of the second swap-back command (step S644), and then the method is completed. Conversely, if the target memory unit of the free buffer bank is occupied (step S642), e.g. the bank indicator is not equal to “0”, a swap-out process and a swap-in process are performed for the target memory unit at the current clock cycle (step S646), and the method is completed. In the swap-out process, the access-management unit reads the target memory unit to obtain the data and the bank indicator stored in the target memory unit, as the swap-out data and the swap-out indicator. In the swap-in process, the access-management unit stores the swap-back data of the third or fourth swap-back command into the target memory unit, and updates the bank indicator of the target memory unit in the free buffer bank according to the swap-back bank index of the current swap-back command. Next, the access-management unit will issue another swap-back command at the next clock cycle (i.e., clock cycle T4).

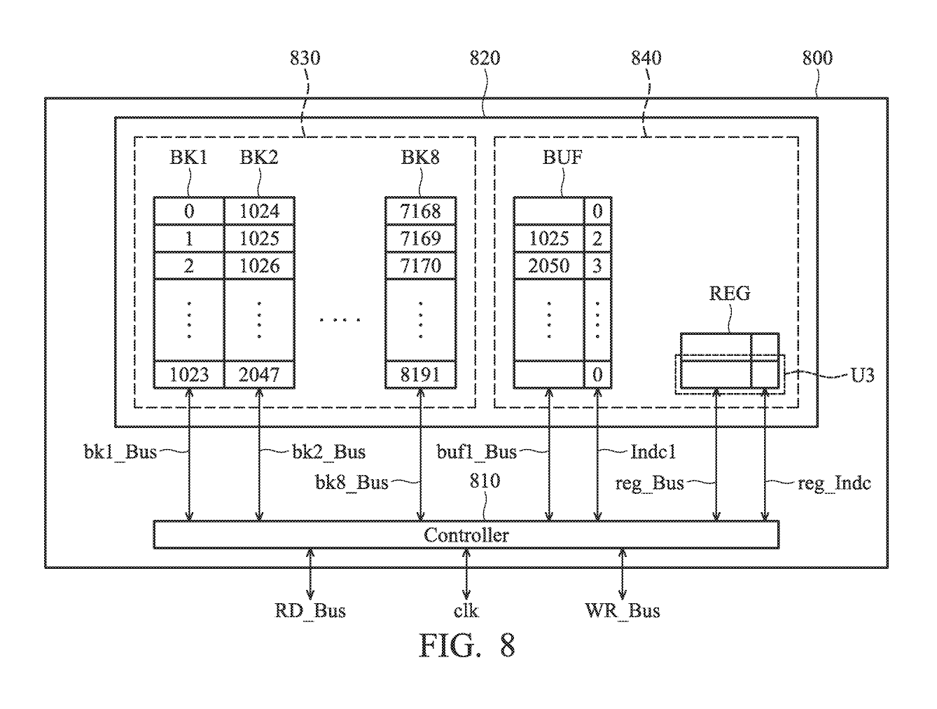

FIG. 8 shows a two-port latency-reduced memory device 800 according to another embodiment of the invention. The two-port memory device 800 comprises a controller 810 and a memory circuit 820, wherein the memory circuit 820 comprises a main part 830 and a buffer part 840. The main part 830 comprises 8 memory banks BK1-BK8, and each of the memory banks BK1-BK8 is a single port memory bank having 1024 memory units U1. The buffer part 840 comprises a buffer bank BUF and a register buffer REG. The buffer bank BUF is a two-port memory bank having 1024 memory units U2. As described above, each memory unit U2 comprises a data area and an indicator area. Furthermore, the register buffer REG comprises one or more memory units U3, wherein each memory unit U3 also comprises a data area and an indicator area. It should be noted that the number of the memory units U3 is determined according to actual applications.

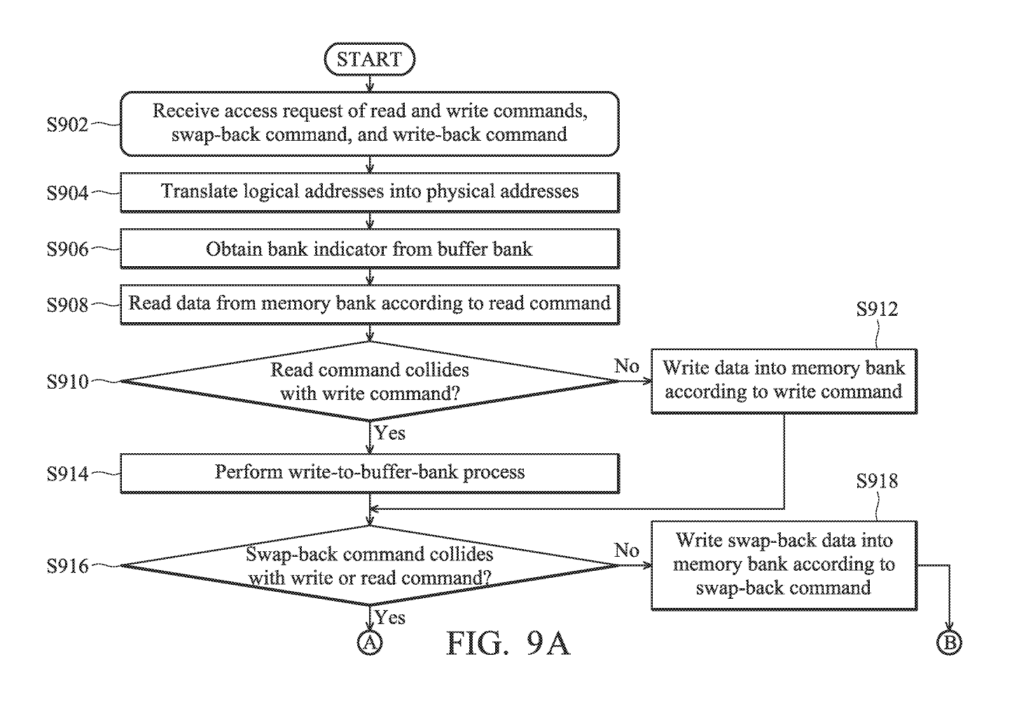

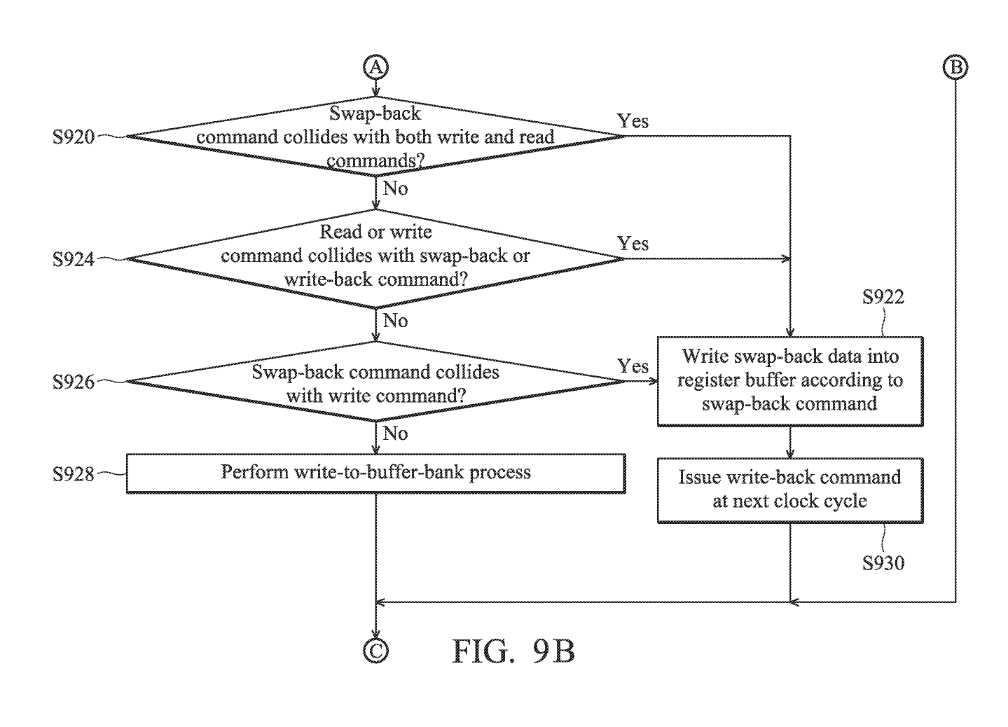

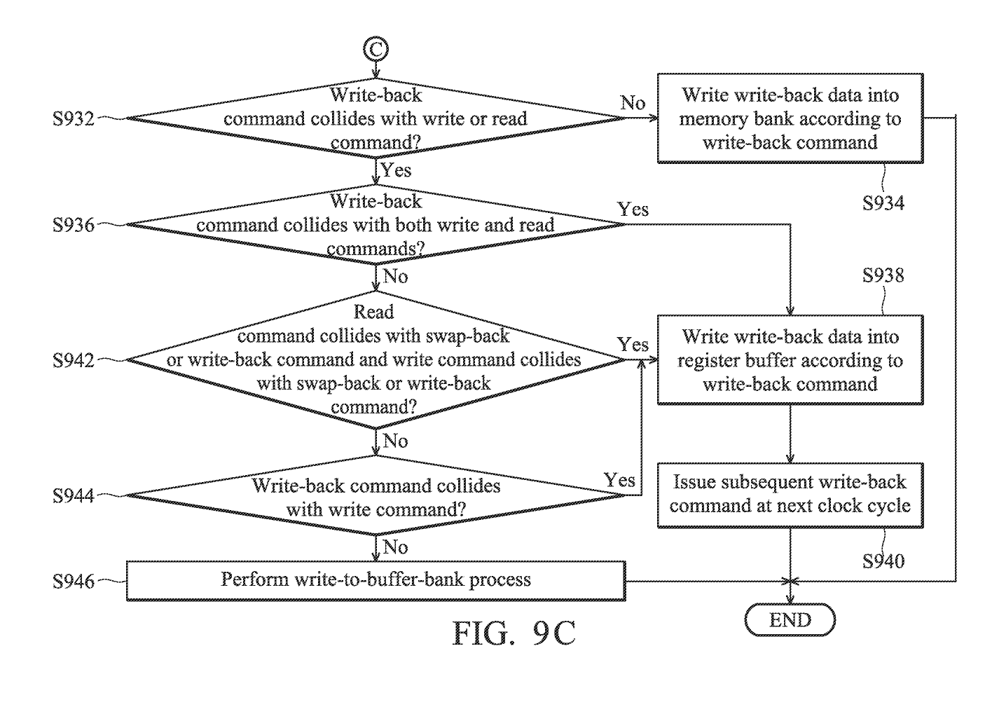

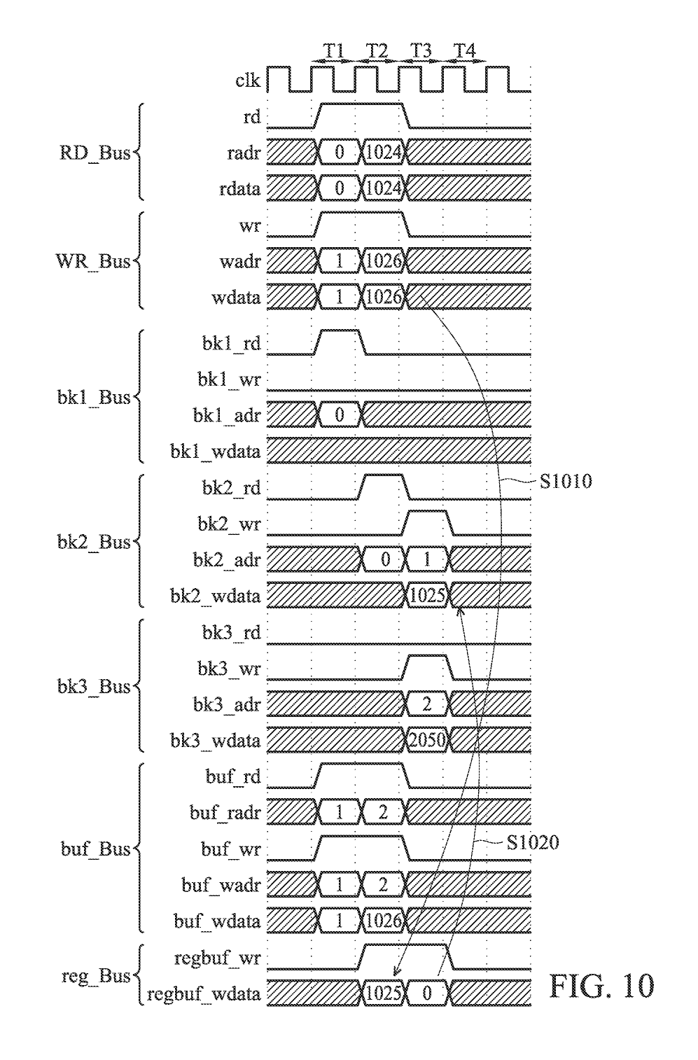

FIGS. 9A-9C show a control method for a latency-reduced memory device according to another embodiment of the invention. FIG. 10 shows an example waveform diagram of the buses of the memory device 800 of FIG. 8 according to the control method of FIGS. 9A-9C. In FIG. 10, the bus RD_Bus comprises a command signal rd, an address signal radr and a data signal rdata for a read port of the memory device 800 in FIG. 8. Furthermore, the bus WR_Bus comprises a command signal wr, an address signal wadr and a data signal wdata for a write port of the memory device 800 in FIG. 8. For each of the memory banks BK1-BK8, each bus comprises two command signals bk#_rd and bk#_wr, an address signal bk#_adr and a data signal bk#_wdata, as described above. Moreover, a bus buf_Bus of the buffer bank BUF comprises a command signal buf_rd, and an address signal buf_radr for a read port, and a command signal buf_wr, an address signal buf_wadr and a data signal buf_wdata for a write port. Furthermore, a bus reg_Bus of the register buffer REG comprises a command signal regbuf_wr, and a data signal regbuf_wdata for a write port.

In this embodiment, the initial content of the memory device 800 is shown in FIG. 8. During clock cycle T1, the memory device 800 receives a read command and a write command as shown in FIG. 10, wherein the read command collides with the write command at the clock cycle T1. The data corresponding to the read command is read from the memory bank BK1. To handle the collision, the data to be written (i.e., “1”) and the corresponding bank index (i.e., “1”) will be written into the second entry of the buffer bank BUF. Since there is already another data stored in the second entry of the buffer bank BUF (i.e., the data “1025”’ and the corresponding bank index “2”), writing data into the second entry of the buffer bank BUF1 (also referred to as a swap-in process) accompanies a swap-out process for the originally stored data, and this situation will introduce a swap-back command at the next clock cycle (i.e., clock cycle T2).

During clock cycle T2, the memory device 800 receives a read command, a write command, and a swap-back command caused by the previous clock cycle T1 as shown in FIG. 10, wherein the read command collides with the write command and the swap-back command collides with both of the read and write commands. The data corresponding to the read command is read from the memory bank BK2. To handle the collision caused by the read and write commands, the data to be written (i.e., “1026”) and the corresponding bank index (i.e., “2”) will be written into the third entry of the buffer bank BUF. Since there is already another data stored in the third entry of the buffer bank BUF (i.e., the data “2050”’ and the corresponding bank index “3”), writing data into the third entry of the buffer bank BUF1 (also referred to as a swap-in process) accompanies a swap-out process for the originally stored data, and this situation will introduce a swap-back command at the next clock cycle (i.e., clock cycle T3). To handle the collision corresponding to the swap-back command caused by the previous clock cycle T1, the data “1025”’ and the corresponding bank index “2” will be written into the register buffer REG, and a corresponding write-back command will be issued at the next clock cycle (i.e., clock cycle T3).

During clock cycle T3, the memory device 800 receives a swap-back command and a write-back command caused by the previous clock cycle T2. Since the swap-back command does not collide with the write-back command, the data “2050” corresponding to the swap-back command will be written into the third entry of the memory bank BK3, while the data “1025” corresponding to the write-back command will be written into the second entry of the memory bank BK2.

A complete diagram of the control method for the memory device 800 is shown in FIGS. 9A-9C. The control method comprises:

Step S902: receiving access request of read and write commands, swap-back command and write-back commend:

Step S904: translating logical addresses into physical addressed;

Step S906: obtaining bank indicator form buffer bank;

Step S908: reading data from memory bank according to read command;

Step S910: determining whether the read command collides with the write command. If the determination result is “yes”, the control method will go to step S914, and if the determination result is “no”, the control method will go to step S912;

Step S912: writing data into memory bank according to write command;

Step S914: performing a write-to-buffer-bank process;

Step S916: determining whether the swap-back command collides with the read or write command. If the determination result is “yes”, the control method will go to step S920, and if the determination result is “no”, the control method will go to step S918;

Step S918: writing the swap-back data into memory bank according to the swap-back command;

Step S920: determining whether the swap-back command collides with the read and write command. If the determination result is “yes”, the control method will go to step S922, and if the determination result is “no”, the control method will go to step S924;

Step S922: writing swap-back data into register buffer according to swap-back command;

Step S924: determining whether the read or write command collides with the swap-back command or the write-back command. If the determination result is “yes”, the control method will go to step S922, and if the determination result is “no”, the control method will go to step S916;

Step S926: determining whether the swap-back command collides with the write command. If the determination result is “yes”, the control method will go to step S922, and if the determination result is “no”, the control method will go to step S928;

Step S928: performing the write-to-buffer-bank process;

Step S930: issuing a write-back command at next clock cycle;

Step S932: determining whether the write-back command collides with the read or write command. If the determination result is “yes”, the control method will go to step S936, and if the determination result is “no”, the control method will go to step S934:

Step S934: writing the write-back data into the memory bank according to the write-back command;

Step S936: determining whether the write-back command collides with both read and write commands. If the determination result is “yes”, the control method will go to step S938, and if the determination result is “no”, the control method will go to step S942;

Step S938: writing the write-back data into the register buffer according to the write-back command;

Step S940: issuing a subsequent write-back command at next clock cycle;

Step S942: determining whether the read command collides with the swap-back command or the write-back command and the write command collides with the swap-back command or the write-back command. If the determination result is “yes”, the control method will go to step S938, and if the determination result is “no”, the control method will go to step S944;

Step S944: determining whether the write-back command collides with the write command. If the determination result is “yes”, the control method will go to step S938, and if the determination result is “no”, the control method will go to step S946;

Step S946: performing the write-to-buffer-bank process.

Please note that the memory device 800 can receive at most a read command, a write command, a swap-back command and a write-back command in one clock cycle. If any of the foregoing commands is absent in a clock cycle, the related steps in FIGS. 9A-9C will be skipped. Taking FIG. 10 as an example, since the memory device 800 only receives a read command and a write command in clock cycle T1, the steps related to the swap-back command and the write-back command will be skipped.

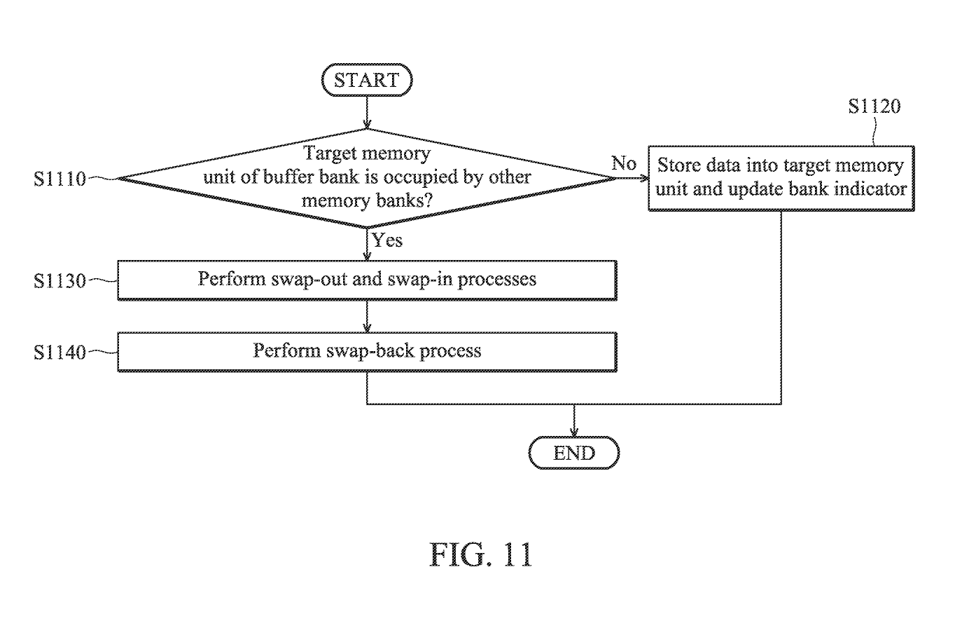

FIG. 11 shows a flow chart illustrating the write-to-buffer-bank process of the control method of FIGS. 9A-9C according to an embodiment of the invention. First, in step S1110, it is determined whether a target memory unit of the buffer bank BUF is occupied by other memory banks, wherein the target memory unit is the memory unit U2 corresponding to the write physical address in the buffer bank BUF, i.e. the bank indicator corresponding to the write physical address is equal to the write bank index. If the target memory unit of the buffer bank BUF is not occupied, e.g. the bank indicator is not equal to “0”, the access-management unit stores the data obtained in the data signal wdata of the bus WR_Bus into the target memory unit of the buffer bank BUF, and updates the bank indicator of the target memory unit in the buffer bank BUF according to the write bank index (step S1120), and then the write-to-buffer-bank process is completed. Conversely, if the target memory unit of the buffer bank BUF is occupied (step S1110), e.g. the bank indicator is not equal to “0”, a swap-out process and a swap-in process are performed for the target memory unit at the current clock cycle (step S1130). In the swap-out process, the access-management unit reads the target memory unit to obtain the data and the bank indicator stored in the target memory unit, as the swap-out data and the swap-out indicator. In the swap-in process, the access-management unit stores the data obtained in the data signal wdata of the bus WR_Bus into the target memory unit, and updates the bank indicator of the target memory unit in the buffer bank BUF according to the write bank index. Next, a swap-back process is performed at the next clock cycle (step S1140), so as to store a swap-back data (i.e. the swap-out data) into the memory unit U1 of the memory bank according to the write physical address and the swap-out indicator, wherein the access-management unit obtains a swap-back address according to the write physical address and the swap-out indicator. Thus, the write-to-buffer-bank process is completed.

According to the embodiment, the buffer banks and the register buffer may be two-port memory banks or logical multi-port memory banks. Furthermore, the bandwidth of the memory device is increased by using the buffer banks and the register buffer to store the collision data. Furthermore, in the embodiments, the data areas of the memory unit U2 of each memory bank in the buffer part (e.g. 170 of FIG. 1, 240 of FIG. 2, 540 of FIGS. 5A-5D and 840 of FIG. 8) are implemented by a SRAM, and the indicator areas of the memory unit U2 of each memory bank in the buffer part are implemented by the registers, such as D flip-flops. In general, the D flip-flop can be immediately read to obtain the bank indicator stored the D flip-flop, thus the memory unit U2 can be completely read during a clock cycle. Furthermore, in another embodiment, the indicator areas of the memory unit U2 of each memory bank in the buffer part are also implemented by the SRAM, so as to replace the D flip-flops with the SRAM, thereby decreasing the chip area of the multi-port memory device. If the memory units U2 are implemented in the SRAM, it needs one clock cycle to read the data area and another clock cycle to read the indicator area.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A memory device, comprising:
a plurality of memory banks, each having a bank index and comprising a plurality of bank memory units for storing data associated with a logical address corresponding to the bank index;
at least one buffer bank, each comprising a plurality of buffer memory units; and
a controller, receiving at least one read command and at least one write command in a first clock cycle, wherein the at least one read command and the at least one write command are requesting to access a specific memory bank among the memory banks,
if an access request of the at least one read command and the at least one write command exceeds a bandwidth limitation of the specific memory bank, the controller utilizes the at least one buffer bank to accomplish the at least one read command and the at least one write command.

2. The memory device as claimed in claim 1, wherein a quantity of the buffer memory units of each of the at least one buffer bank is equal to a quantity of the bank memory units of each of the memory banks, and the bank memory units of the memory banks having the same entry index correspond to the same buffer memory unit of each of the at least one buffer bank.

3. The memory device as claimed in claim 1, wherein a quantity of the buffer memory units of each of the at least one buffer bank is larger than a quantity of the bank memory units of each of the memory banks.

4. The memory device as claimed in claim 1, the at least one buffer bank is capable of reading and writing simultaneously, wherein each of the memory banks and the at least one buffer bank are able to operate concurrently and independent of each other.

5. The memory device as claimed in claim 1, wherein when the access request of the read command and the write command exceeds the bandwidth limitation of the specific memory bank, the controller determines whether a collision exists according to logical addresses of the read and write commands and an indicator of the buffer memory unit of the at least one buffer bank having an entry index corresponding to the logical addresses, wherein when no collision exists, the controller stores first data corresponding to the write command into the bank memory unit of the memory bank or the buffer memory unit according to the logical address of the write command and the indicator of the buffer memory unit having the entry index corresponding to the logical addresses, and reads the bank memory unit of the memory bank or the buffer memory unit according to the logical address of the read command and the indicator of the buffer memory unit having the entry index corresponding to the logical addresses, and when the collision exists and a read data corresponding to the read command is stored in the bank memory unit of the memory bank, the controller performs a write-to-buffer-bank process.

6. The memory device as claimed in claim 5, wherein when the collision exists, the controller reads the bank memory unit of the specific memory bank or the buffer memory unit in a second clock cycle immediately following the first clock cycle, and when the write-to-buffer-bank process is performed, the controller determines whether a specific buffer memory unit of the buffer bank corresponding to the logical address of the write command is blank, and if the specific buffer memory unit is blank, the controller stores the first data into the specific buffer memory unit and stores a bank index of the specific memory bank into the specific buffer memory unit as a bank indicator, and if the specific buffer memory unit is not blank, the controller moves second data stored in the specific buffer memory unit to the bank memory unit of the memory bank having the bank index corresponding to the bank indicator of the specific second memory, and stores the first data into the specific buffer memory unit and updates the bank indicator after the second data is removed.

7. The memory device as claimed in claim 5, wherein the controller reads the bank memory unit of the specific memory bank in the first clock cycle according to the logical address of the read command.

8. The memory device as claimed in claim 5, wherein when the collision exists, the controller further utilizes a plurality of buffer banks to perform the write-to-buffer-bank process, and the controller determines whether a specific buffer memory unit of a first buffer bank corresponding to the logical address of the write command is blank, if the specific buffer memory unit is not blank and a bank indicator of the specific buffer memory unit of the first buffer bank corresponds to the logical address of the read or write command, the controller moves the bank indicator and second data stored in the specific buffer memory unit of the first buffer bank into a second buffer bank, wherein the second buffer bank has no swap-back collision in a second clock cycle immediately following the first clock cycle.

9. The memory device as claimed in claim 5, wherein when the collision exists, the controller further utilizes at least one register memory unit to perform the write-to-buffer-bank process, and the controller determines whether a specific buffer memory unit of the buffer bank corresponding to the logical address of the write command is blank, if the specific buffer memory unit of the buffer bank is not blank and a bank indicator from the specific buffer memory unit of the buffer bank corresponds to the logical address of the read or write command, the controller moves the bank indicator and second data stored in the specific buffer memory unit of the buffer bank into the register memory unit in the first clock cycle.

10. The memory device as claimed in claim 9, wherein the controller moves the second data stored in the register memory unit to one of the bank memory units having the bank index corresponding to the bank indicator in a second clock cycle immediately following the first clock cycle.

11. The memory device as claimed in claim 10, wherein the controller further stores the logical address of the read or write command into the register memory unit in the first clock cycle, so as to move the second data into the bank memory unit corresponding to the logical address in the memory bank.

12. A control method for accessing a memory device, wherein the memory device comprising a plurality of memory banks and at least one buffer bank, comprising:
receiving at least one read command and at least one write command in a first clock cycle, wherein the at least one read command and the at least one write command are requesting to access a specific memory bank among the memory banks; and
utilizing the at least one buffer bank to accomplish the at least one read command and the at least one write command when an access request of the at least one read command and the at least one write command exceeds a bandwidth limitation of the specific memory bank,
wherein each of the memory banks has a bank index and comprises a plurality of bank memory units for storing data associated with a logical address corresponding to the bank index, and each of the least one buffer bank comprises a plurality of buffer memory units.

13. The control method as claimed in claim 12, wherein a quantity of the buffer memory units of each of the at least one buffer bank is equal to a quantity of the bank memory units of each of the memory banks, and the bank memory units of the memory banks having the same entry index correspond to the same buffer memory unit of each of the at least one buffer bank.

14. The control method as claimed in claim 12, wherein a quantity of the buffer memory units of each of the at least one buffer bank is larger than a quantity of the bank memory units of each of the memory banks.

15. The control method as claimed in claim 12, the at least one buffer bank is capable of reading and writing simultaneously, wherein each of the memory banks and the at least one buffer bank are able to operate concurrently and independent of each other.

16. The control method as claimed in claim 12, wherein the step of utilizing the at least one buffer bank to accomplish the at least one read command and the at least one write command further comprises:
determines whether a collision exists according to logical addresses of the read and write commands and an indicator of the buffer memory unit of the at least one buffer bank having an entry index corresponding to the logical addresses;
when no collision exists, storing first data corresponding to the write command into the bank memory unit of the memory bank or the buffer memory unit according to the logical address of the write command and the indicator of the buffer memory unit having the entry index corresponding to the logical addresses, and reading the bank memory unit of the memory bank or the buffer memory unit according to the logical address of the read command and the indicator of the buffer memory unit having the entry index corresponding to the logical addresses; and
when the collision exists and a read data corresponding to the read command is stored in the bank memory unit of the memory bank, performing a write-to-buffer-bank process.

17. The control method as claimed in claim 16, wherein the step of utilizing the at least one buffer bank to accomplish the at least one read command and the at least one write command further comprises:
reading the bank memory unit of the specific memory bank or the buffer memory unit in a second clock cycle immediately following the first clock cycle;
wherein the step of performing the write-to-buffer-bank process further comprises:
determining whether a specific buffer memory unit of the buffer bank corresponding to the logical address of the write command is blank;
if the specific buffer memory unit is blank, storing the first data into the specific buffer memory unit and storing a bank index of the specific memory bank into the specific buffer memory unit as a bank indicator;
if the specific buffer memory unit is not blank, moving second data stored in the specific buffer memory unit to the bank memory unit of the memory bank having the bank index corresponding to the bank indicator of the specific second memory; and
storing the first data into the specific buffer memory unit and updating the bank indicator after the second data is removed.

18. The control method as claimed in claim 16, further comprising:
reads the bank memory unit of the specific memory bank in the first clock cycle according to the logical address of the read command.

19. The control method as claimed in claim 16, wherein the step of utilizing the at least one buffer bank to accomplish the at least one read command and the at least one write command further comprises:
utilizing a plurality of buffer banks or at least one register memory unit to perform the write-to-buffer-bank process when the collision exists.

20. The control method as claimed in claim 19, further comprising:
determining whether a specific buffer memory unit of a first buffer bank corresponding to the logical address of the write command is blank; and
if the specific buffer memory unit is not blank and a bank indicator of the specific buffer memory unit of the first buffer bank corresponds to the logical address of the read or write command, moving the bank indicator and second data stored in the specific buffer memory unit of the first buffer bank into a second buffer bank,
wherein the second buffer bank has no swap-back collision in a second clock cycle immediately following the first clock cycle.

21. The control method as claimed in claim 19, further comprising:
determining whether a specific buffer memory unit of the buffer bank corresponding to the logical address of the write command is blank; and
if the specific buffer memory unit of the buffer bank is not blank and a bank indicator from the specific buffer memory unit of the buffer bank corresponds to the logical address of the read or write command, moving the bank indicator and second data stored in the specific buffer memory unit of the buffer bank into the register memory unit in the first clock cycle.

22. The control method as claimed in claim 21, further comprising:
moving the second data stored in the register memory unit to one of the bank memory units having the bank index corresponding to the bank indicator in a second clock cycle immediately following the first clock cycle.

23. The control method as claimed in claim 22, wherein the step of moving the second data stored in the register memory unit to the one of the bank memory units having the bank index corresponding to the bank indicator in a second clock cycle immediately following the first clock cycle further comprising:
storing the logical address of the read or write command into the register memory unit in the first clock cycle; and
moving the second data into the bank memory unit corresponding to the logical address in the memory bank.
